(19) United States
(12) Patent Application Publication
(10) Pub. No.: US 2025/0362723 A1
(43) Pub. Date: Nov. 27, 2025

(54) COOLING DEVICE AND COMPUTER SYSTEM INCLUDING A COOLING DEVICE

(71) Applicant: Samsung Electronics Co., Ltd., Suwon-si (KR)

(72) Inventors: Shailabh Kumar, Pasadena, CA (US); Radwanul Hasan Siddique, Monrovia, CA (US); Yibing Michelle Wang, Pasadena, CA (US); Haeri Park Hanania, Sierra Madre, CA (US)

(21) Appl. No.: 18/823,048

(22) Filed: Sep. 3, 2024

Related U.S. Application Data
(60) Provisional application No. 63/650,787, filed on May 22, 2024.

(51) Int. Cl. G06F 1/20; H05K 7/20

(52) U.S. Cl. CPC G06F 1/20; H05K 7/20218

(57) ABSTRACT

A cooling system includes a cooling device having a housing defining an interior chamber; an inlet in the housing; an outlet in the housing; and a number of cooling channels at an interface surface of the housing and between the inlet and the outlet. The cooling system may also include a coolant in the interior chamber of the housing, and a nanocoating and/or nanostructures on the cooling channels that are configured to reduce the flow resistance of the coolant flowing in the cooling channels. The cooling channels may be microfluidic channels or nanofluidic channels. The coolant may include an additive and/or metallic nanoparticles.

### CROSS-REFERENCE TO RELATED APPLICATION(S)

The present application claims priority to and the benefit of U.S. Provisional Application No. 63/650,787, filed May 22, 2024, entitled “In-Chip & Off-Chip Nanofluidic Cooling Solutions for HPC, Data Centers, Supercomputers,” the entire content of which is incorporated herein by reference.

### BACKGROUND

### 1. Field

The present disclosure relates to various embodiments of cooling devices.

### 2. Description of the Related Art

Thermal management of computer components, such as memory and processor chiplets, poses several challenges, including heat transfer through multiple layers of materials and different target temperatures for specific devices and materials. Some related art cooling devices utilize forced air, but such devices can only sufficiently cool heat densities up to approximately 1 W/mm² and may have a heat dissipation, Q, of approximately 85 W/cm². Other related art cooling devices utilize a single-phase liquid coolant flowing through a heat sink attached to the heat-generating components. Interfacing the liquid coolant heat sinks to the logic chips and/or other high-heat components determines the effective heat dissipation. Accordingly, these related art liquid cooling heat sinks may have a heat dissipation, Q, of approximately 250 W/cm² to approximately 460 W/cm².

The above information disclosed in this Background section is only to enhance understanding of background information pertaining to the present disclosure and may contain information that does not constitute prior art.

### SUMMARY

The present disclosure relates to various embodiments of a cooling system. In one embodiment, the cooling system includes a cooling device including a housing defining an interior chamber, an inlet in the housing, an outlet in the housing, and cooling channels at an interface surface of the housing and between the inlet and the outlet.

The cooling system may also include a coolant in the interior chamber of the housing.

The cooling channels may include microfluidic channels and/or nanofluidic channels.

The cooling system may include a nanocoating on the cooling channels.

The cooling system may include nanostructures on the cooling channels.

The cooling system may include a heat exchanger connected to the outlet that is configured to receive the coolant from the outlet.

The cooling system may include a flow controller connected to the inlet that is configured to pump the coolant into the housing through the inlet.

The coolant may include a liquid.

The liquid may include water, a dielectric fluid, a synthetic oil, and/or a perfluorocarbon compound. The liquid may include at least one additive.

The additive may be an antifreeze agent, such as glycerol, ethylene glycol, methylene glycol, and/or methanol.

The additive may be a viscosity modifier, a corrosion inhibitor, a biocidal agent, an antifoaming agent, a pH buffer, and/or a dye.

The cooling system may include metallic nanoparticles in the coolant.

The metallic nanoparticles may include a metal such as aluminum, copper, and/or silver, and a passivation layer on top of the metal.

The cooling system may include pressure sensors configured to measure a pressure drop in the plurality of cooling channels including a first pressure sensor at the inlet and a second pressure sensor at the outlet.

The cooling system may include flow sensors configured to measure a flow rate through the plurality of cooling channels including a first flow sensor at the inlet and a second flow sensor at the outlet.

The cooling system may include temperature sensors configured to measure a temperature in the plurality of cooling channels including a first temperature sensor at the inlet and a second temperature sensor at the outlet.

The present disclosure also relates to various embodiments of a computer chip with an in-chip cooling device. In one embodiment, the computer chip includes a housing defining an interior chamber; a computing device in the housing; an inlet in the housing; an outlet in the housing; and cooling channels between the inlet and the outlet. The cooling channels include microfluidic channels and/or nanofluidic channels.

The cooling device may include a nanocoating and/or nanostructures on the cooling channels.

The present disclosure also relates to various embodiments of a computing system. In one embodiment, the computing system includes a system board; a substrate or an interposer on the system board; a computing device on the substrate or the interposer; and a cooling device between the computing device and the substrate or the interposer.

The cooling device includes a housing defining an interior chamber and an interface surface in contact with the computing device; an inlet in the housing; an outlet in the housing; and cooling channels in the interior chamber at the interface surface and between the inlet and the outlet; a coolant in the interior chamber of the housing; a flow controller connected to the inlet that is configured to pump the coolant into the housing through the inlet; and a heat exchanger connected to the outlet that is configured to receive the coolant from the outlet.

This summary is provided to introduce a selection of features and concepts of embodiments of the present disclosure that are further described below in the detailed description. This summary is not intended to identify key or essential features of the claimed subject matter, nor is it intended to be used in limiting the scope of the claimed subject matter. One or more of the described features or tasks may be combined with one or more other described features or tasks to provide a workable method or system.

### BRIEF DESCRIPTION OF THE DRAWINGS

The features and advantages of embodiments of the present disclosure will be better understood by reference to the following detailed description when considered in conjunction with the drawings. The drawings are not necessarily drawn to scale.

FIG. 1 is a perspective view of a cooling system according to one embodiment of the present disclosure;

FIG. 2A is a side view of the cooling system according to one embodiment of the present disclosure;

FIG. 2B is a side view of the cooling system according to another embodiment of the present disclosure;

FIG. 3 is a perspective view of a cooling device or module of the embodiment of the cooling system illustrated in FIGS. 1-2;

FIG. 4 is a cross-sectional view of the cooling device according to one embodiment of the present disclosure; and

FIG. 5 is a cross-sectional view of a computer system including a computer chip with an in-chip cooling device according to one embodiment of the present disclosure.

### DETAILED DESCRIPTION

The present disclosure relates to various embodiments of a cooling device or module for a computer system or one or more computer components of a computer system, such as a memory chip and/or a logic chip. In one or more embodiments, the cooling device may be separate from the computer component (e.g., the memory chip or the logic chip) or the cooling device may be integrated into the computer component. The cooling device according to one or more embodiments of the present disclosure includes a plurality of cooling channels (e.g., micro-or nano-cooling channels) that are configured to increase the surface area of the cooling device in contact with a computer component, such as a memory chip and/or a logic chip, which increases the cooling capacity of the cooling device. A coolant flowing through the cooling channels is configured to dissipate heat from the computer component to the surrounding environment. In one or more embodiments, the cooling device may include a coating or film on the cooling channels that is configured to reduce the flow resistance of the coolant flowing in the cooling channels.

Hereinafter, example embodiments will be described in more detail with reference to the accompanying drawings, in which like reference numbers refer to like elements throughout. The present invention, however, may be embodied in various different forms, and should not be construed as being limited to only the illustrated embodiments herein. Rather, these embodiments are provided as examples so that this disclosure will be thorough and complete, and will fully convey the aspects and features of the present invention to those skilled in the art. Accordingly, processes, elements, and techniques that are not necessary to those having ordinary skill in the art for a complete understanding of the aspects and features of the present invention may not be described. Unless otherwise noted, like reference numerals denote like elements throughout the attached drawings and the written description, and thus, descriptions thereof may not be repeated.

In the drawings, the relative sizes of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present invention.

The terminology used herein is for the purpose of describing particular embodiments and is not intended to be limiting of the present invention. As used herein, the singular forms “a” and “an” are intended to include the plural forms as well, unless the context clearly indicates otherwise. It will be further understood that the terms “comprises,” “comprising,” “includes,” and “including,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Expressions such as “at least one of,” when preceding a list of elements, modify the entire list of elements and do not modify the individual elements of the list.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present invention refers to “one or more embodiments of the present invention.” As used herein, the terms “use,” “using,” and “used” may be considered synonymous with the terms “utilize,” “utilizing,” and “utilized,” respectively. Also, the term “exemplary” is intended to refer to an example or illustration.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

For the purposes of this disclosure, expressions such as “at least one of,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, YZ, and ZZ, or any variation thereof. Similarly, the expression such as “at least one of A and B” may include A, B, or A and B. As used herein, “or” generally means “and/or,” and the term “and/or” includes any and all combinations of one or more of the associated listed items. For example, the expression such as “A and/or B” may include A, B, or A and B.

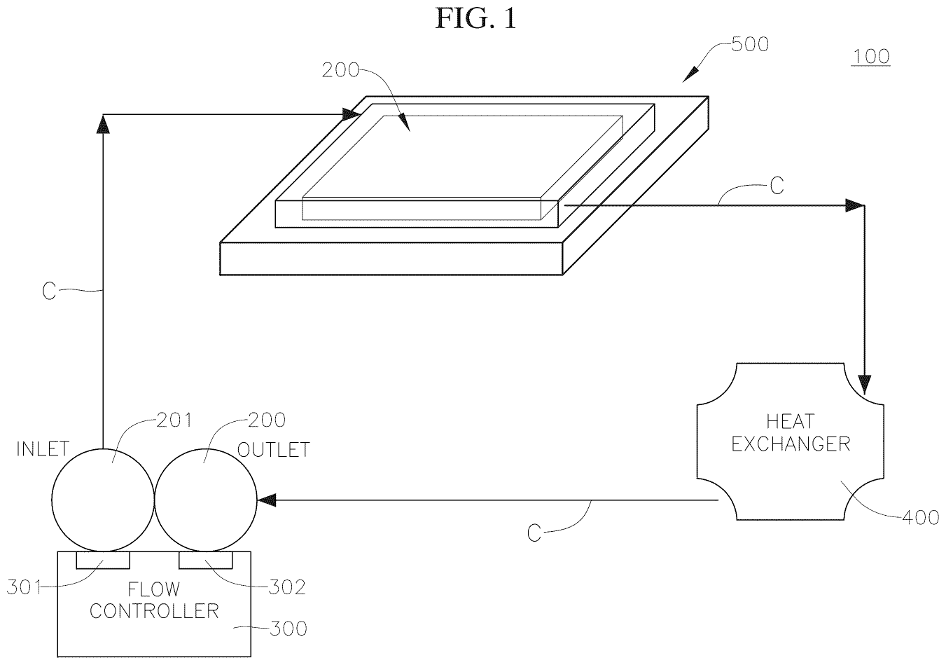

With reference now to FIG. 1, a cooling system 100 according to one embodiment of the present disclosure includes a cooling device or module 200 having an inlet 201 and an outlet 202. The cooling system 100 also includes a flow controller 300 including an outlet 301 and an inlet 302. The outlet 301 of the flow controller 300 is configured to direct (e.g., pump) a coolant C into the inlet 201 of the cooling device 200. The cooling system 100 also includes a heat exchanger 400 between the outlet 202 of the cooling device 200 and the inlet 302 of the flow controller 300. The heat exchanger 400 is configured to receive the heated coolant C after it passes through the cooling device 200, dissipate at least some of the heat from the coolant to the surrounding environment, and then pass the cooled coolant to the flow controller 300, which returns the cooled coolant C to the cooling device 200 in a closed loop manner.

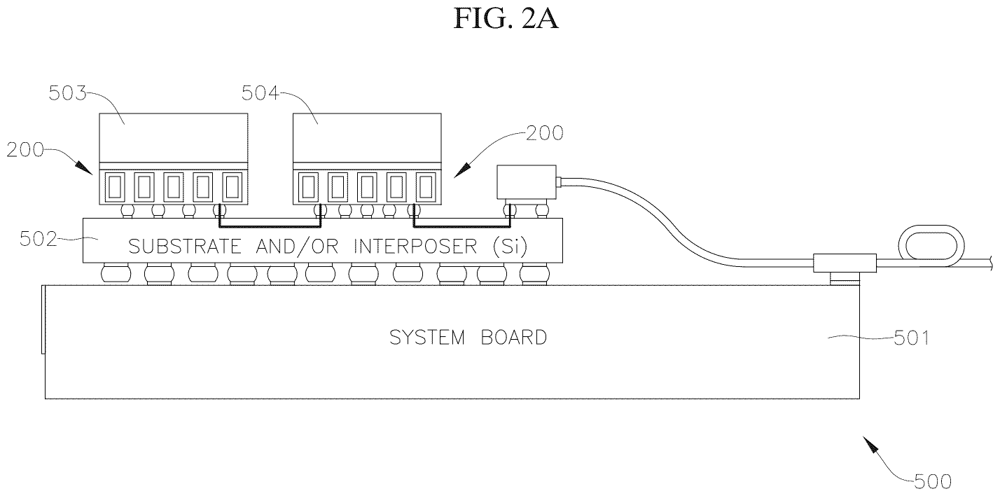

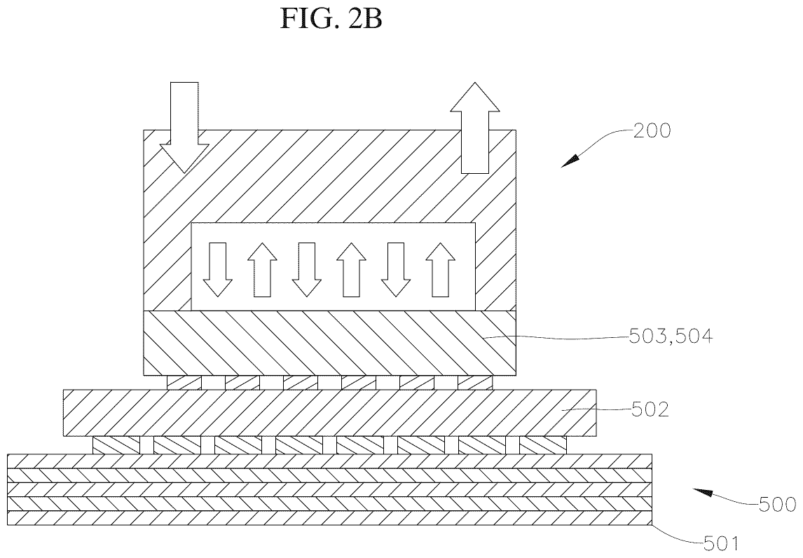

The cooling system 100 is configured to dissipate heat from one or more heat-generating components of a computer system 500. With reference now to FIG. 2A, the computer system 500 includes a system board 501, a substrate and/or an interposer 502 (e.g., a silicon substrate and/or interposer) on the system board 501, and a memory chip 503 (e.g., a high bandwidth memory (HBM) chip) and a logic chip 504 (e.g., an xPU, such as a data processing unit (DPU), an infrastructure processing unit (IPU), a function accelerator card (FAC), or a network attached processing unit (NAPU)) on the substrate and/or the interposer 501. In the illustrated embodiment, one of the cooling devices 200 is between the substrate/interposer 502 and the memory chip 503, and another one of the cooling devices 200 is between the substrate/interposer 502 and the logic chip 504.

Although in one or more embodiments each heat-generating component of the computer system 500 may be in contact with one corresponding cooling device 200 such that the number of cooling devices 200 is equal to the combined number of memory chip(s) 503 and logic chip(s) 504 of the computer system 500, in one or more embodiments the number of cooling devices 200 may be different than the combined number of memory chip(s) 503 and logic chip(s) 504 of the computer system 500, depending, for instance, on the heat generated by the various components of the computer system 500 and the system requirements. In one or more embodiments, the memory chip 503 may be directly on one of the cooling devices 200 and/or the logic chip 504 may be directly on the other one of the cooling devices 200. In one or more embodiments, the memory chip 503 and/or the logic chip 504 may be thermally coupled to the cooling devices 200, such as with a thermal paste.

Additionally, in one or more embodiments, the memory chip 503 and the logic chip 504 may be thermally coupled to each other. In one or more embodiments, the memory chip 503 and/or the logic chip 504 may be on the cooling device 200, as illustrated in FIG. 2B.

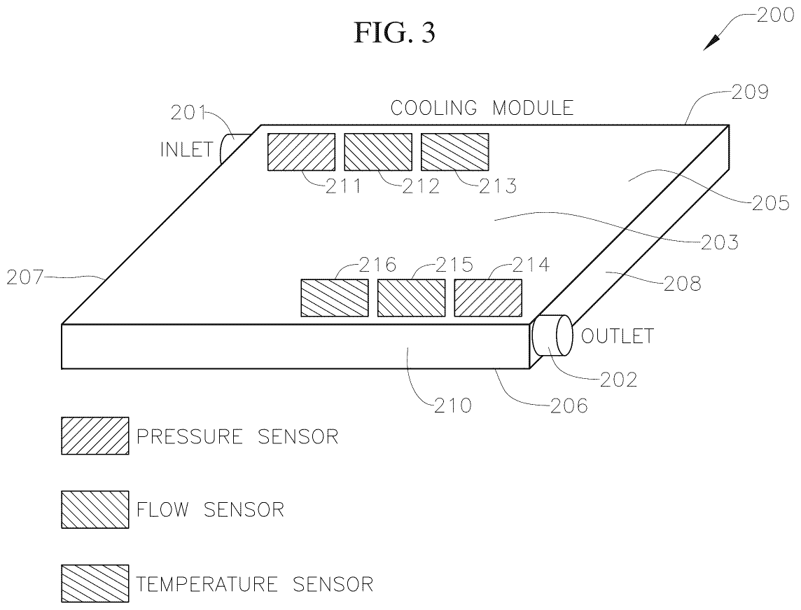

With reference now to FIG. 3, each of the cooling devices 200 includes a body or housing 203 defining an inner chamber or cavity 204. In the illustrated embodiment, the body 203 of the cooling device 200 has a prismatic shape, such as a square cuboid, having a front wall 205 (i.e., an interface wall configured to contact one of the heat generating computer components), a rear wall 206 opposite to the front wall 205, a pair of sidewalls 207, 208 connecting side edges of the front and rear walls 205, 206 to each other, and a pair of end walls 209, 210 connecting end edges of the front and rear walls 205, 206 to each other. In the illustrated embodiment, the inlet 201 is in one of the sidewalls 207 and the outlet 202 is in the other (i.e., opposite) sidewall 208. Additionally, in the illustrated embodiment, the cooling device 200 includes a first pressure sensor 211, a first flow sensor 212, and a first temperature sensor 213 on the housing 203 proximate to the inlet 201, and a second pressure sensor 214, a second flow sensor 215, and a second temperature sensor 216 on the housing 203 proximate to the outlet 202.

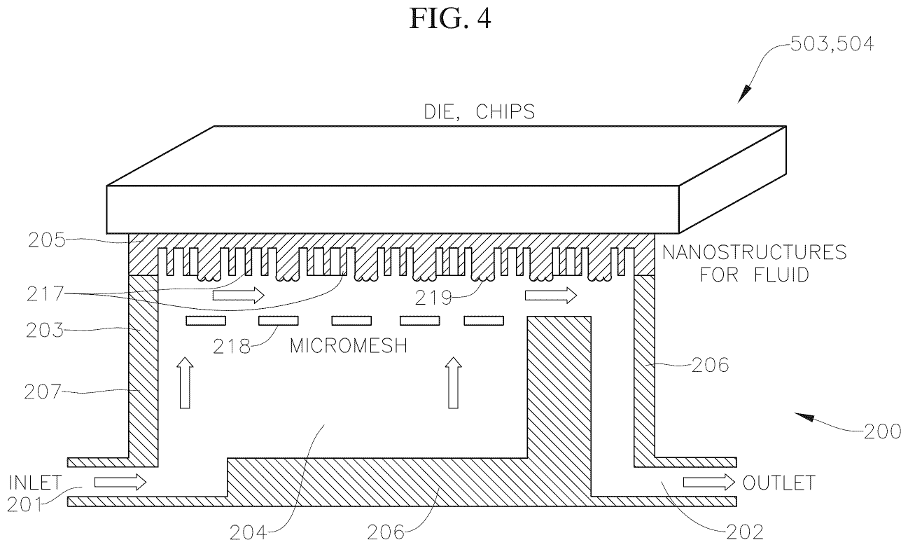

With reference now to FIG. 4, the cooling device 200 includes a plurality of cooling channels 217 at the front wall 205 of the body 203 (i.e., the wall 205 of the cooling device 200 that interfaces with the computer component to be cooled, such as the memory chip(s) 503 and/or the logic chip(s) 504). In one or more embodiments, the cooling channels 217 may be nano-cooling channels (e.g., the nano-cooling channels 217 may have a width in a range from approximately 100 nm to approximately 10,000 nm). In one or more embodiments, the cooling channels 217 may be micro-cooling channels (e.g., the micro-cooling channels 217 may have a width less than approximately 10 microns, less than approximately 5 microns, or less than approximately 3 microns). The cooling channels 217 are configured to increase the surface area of the front wall 205 that interfaces with the computer component to be cooled, which increases the cooling efficiency of the cooling device 200.

In one or more embodiments, the cooling device 200 may include one or more manifolds in the inner chamber 204 that is/are configured to improve the transport of the coolant C to and/or through the cooling channels 217. In one or more embodiments, the cooling device 200 includes a micromesh 218 in the inner chamber 204 that is proximate to the cooling channels 217.

In one or more embodiments, the cooling device 200 may include a film and/or a coating 219 on the cooling channels 217. The film and/or coating 219 is configured to reduce the flow resistance of the coolant C flowing in the cooling channels 217 and thereby increase the flowrate of the coolant C flowing in the cooling channels 217. In one or more embodiments, the cooling device 200 may include a nanocoating on the cooling channels 211. In one or more embodiments, the cooling device 200 may include surface features, such as nanostructures, on the cooling channels 217 that are configured to reduce the flow resistance and thereby increase the flow rate of the coolant C in the cooling channels 217. In one or more embodiments, the cooling channels 217 may include a nanohole array, as described in Kumar et al., “Millimeter-Sized Suspended Plasmonic Nanohole Arrays for Surface-Tension-Driven Flow-Through SERS” doi: 10.1021/cm5031848, the entire content of which is incorporated herein by reference.

In one or more embodiments, the cooling channels 217 may include one or more CMOS processed materials, such as silicon (Si), silicon nitride (SiN), silicon oxide (SiO), aluminum (Al), copper (Cu), and/or organic polymers.

In one or more embodiments, the coolant C flowing in the cooling channels 217 may be a liquid and/or other fluids, such as one or more dielectric fluids, synthetic oils, perfluorocarbon compounds, or combinations thereof. In one or more embodiments, the liquid may be water. In one or more embodiments, the liquid may be mixed with an additive, such as an antifreeze agent (e.g., glycerol, ethylene glycol, methylene glycol, and/or methanol), viscosity modifiers, corrosion inhibitors, biocidal agents (configured to prevent bacterial growth), anti-foaming agents, pH buffers, dyes, etc. In one or more embodiments, the fluid (e.g., liquid) may be mixed with metallic nanoparticles, such as aluminum (Al), copper (Cu), and/or silver (Ag) nanoparticles. In one or more embodiments, the metallic nanoparticles may be coated with one or more passivation layers (e.g., one or more metal oxides). Additionally, in one or more embodiments, the metallic nanoparticles may include one or more non-metallic components. Suitable metallic nanoparticles or nanostructures are described in U.S. Patent Application Publication No. 2023/0234064A1, the entire content of which is incorporated herein by reference. The additive and/or the nanoparticles are configured to increase the thermal capture capacity and the pumping efficiency of the coolant C by balancing the thermal conductivity and the viscosity of the coolant C. Accordingly, in one or more embodiments, the cooling device 200 may have a heat dissipation, Q, of greater than approximately 1,000 W/cm² and a heat transfer coefficient, h, greater than approximately 10,000 W/m²K.

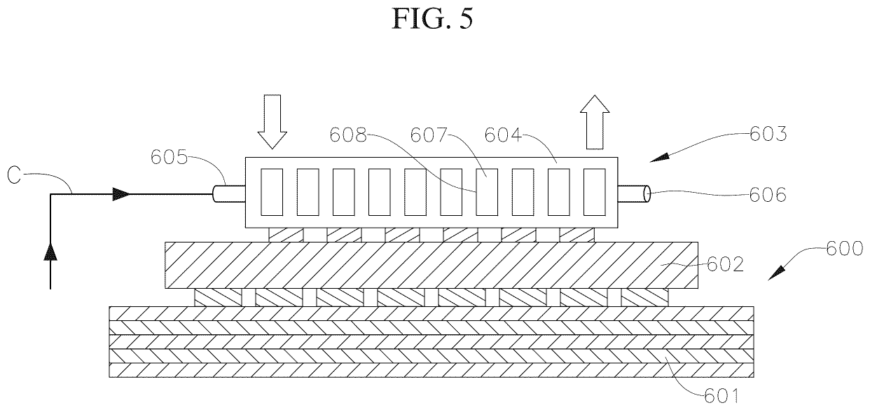

Although FIGS. 1-4 depict a computing system (i.e., systems including semiconductor chips for computational, sensing, quantum computing, optical interconnects, or other applications) according to one embodiment in which the cooling device 200 is separate from the computer component to be cooled (e.g., the memory chip 503 and/or the logic chip 504), in one or more embodiments the cooling device 200 may be integrated into (or integral with) the computer component to be cooled. FIG. 5 is a cross-sectional view of a computer system including a computer chip with an in-chip cooling device according to one embodiment of the present disclosure. In the embodiment illustrated in FIG. 5, the computer system 600 includes a system board 601, a substrate and/or an interposer 602 (e.g., a silicon substrate and/or interposer) on the system board 601, and a computer chip with an integrated in-chip cooling device 603 on the substrate and/or the interposer 601. The computer chip with in-chip cooling 603 may include any suitable type or kind of computing device, such as a memory chip (e.g., a high bandwidth memory (HBM) chip) and/or a logic chip (e.g., an xPU, such as a data processing unit (DPU), an infrastructure processing unit (IPU), a function accelerator card (FAC), or a network attached processing unit (NAPU)).

The computer chip with in-chip cooling 603 may be the same as or similar to the cooling device 200 except the computer chip with in-chip cooling 603 includes a body or housing 604 defining an inner chamber or cavity housing the computing device (e.g., the memory chip or the logic chip). In the illustrated embodiment, the body 604 of the computer chip with in-chip cooling 603 has a prismatic shape, such as a square cuboid, having a front wall, a rear wall opposite to the front wall, a pair of sidewalls connecting side edges of the front and rear walls to each other, and a pair of end walls connecting end edges of the front and rear walls to each other. In the illustrated embodiment, the computer chip with in-chip cooling 603 also includes an inlet 605 in one of the sidewalls and an outlet 606 in the other (i.e., opposite) sidewall.

In the illustrated embodiment, the computer chip with in-chip cooling 603 includes a plurality of cooling channels 607 in the inner chamber 604 at the front wall of the body 604. In one or more embodiments, the cooling channels 607 may be nano-cooling channels (e.g., the nano-cooling channels 607 may have a width in a range from approximately 100 nm to approximately 10,000 nm) and/or the cooling channels 607 may be micro-cooling channels (e.g., the micro-cooling channels 607 may have a width less than approximately 10 microns, less than approximately 5 microns, or less than approximately 3 microns). The cooling channels 607 are configured to increase the surface area of the front wall, which increases the cooling efficiency of the computer chip with in-chip cooling 603.

In one or more embodiments, the computer chip with in-chip cooling 603 may include one or more manifolds in the inner chamber that is/are configured to improve the transport of the coolant C to and/or through the cooling channels 607. In one or more embodiments, the computer chip with in-chip cooling 603 includes a micromesh in the inner chamber that is proximate to the cooling channels 607.

In one or more embodiments, the computer chip with in-chip cooling 603 may include a film and/or a coating 608 on the cooling channels 613. The film and/or coating 608 is configured to reduce the flow resistance of the coolant C flowing in the cooling channels 607 and thereby increase the flowrate of the coolant C flowing in the cooling channels 607. In one or more embodiments, the computer chip with in-chip cooling 603 may include a nanocoating on the cooling channels 607. In one or more embodiments, the computer chip with in-chip cooling 603 may include surface features, such as nanostructures, on the cooling channels 607 that are configured to reduce the flow resistance and thereby increase the flow rate of the coolant C in the cooling channels 607. In one or more embodiments, the cooling channels 607 may include a nanohole array, as described in Kumar et al., “Millimeter-Sized Suspended Plasmonic Nanohole Arrays for Surface-Tension-Driven Flow-Through SERS” doi: 10.1021/cm5031848, the entire content of which is incorporated herein by reference.

In one or more embodiments, the cooling channels 607 may include one or more CMOS processed materials, such as silicon (Si), silicon nitride (SIN), silicon oxide (SiO), aluminum (AI), copper (Cu), and/or organic polymers.

The coolant C flowing through the computer chip with in-chip cooling 603 may be the same as or similar to the coolant C described above with reference to the embodiment depicted in FIGS. 1-4. For instance, in one or more embodiments, the coolant C may liquid and/or other fluids, such as one or more dielectric fluids, synthetic oils, perfluorocarbon compounds, or combinations thereof. In one or more embodiments, the coolant C may be water. In one or more embodiments, the coolant C may be mixed with an additive, such as an antifreeze agent (e.g., glycerol, ethylene glycol, methylene glycol, and/or methanol), viscosity modifiers, corrosion inhibitors, biocidal agents (configured to prevent bacterial growth), anti-foaming agents, pH buffers, dyes, etc. In one or more embodiments, the fluid (e.g., liquid) may be mixed with metallic nanoparticles, such as aluminum (Al), copper (Cu), and/or silver (Ag) nanoparticles. In one or more embodiments, the metallic nanoparticles may be coated with one or more passivation layers (e.g., one or more metal oxides). Additionally, in one or more embodiments, the metallic nanoparticles may include one or more non-metallic components.

In one or more embodiments, the computer system 600 also includes a flow controller including an outlet and an inlet. The outlet of the flow controller is configured to direct (e.g., pump) the coolant C into the inlet 605 of the computer chip with in-chip cooling 603. The computer system 600 also includes a heat exchanger between the outlet 606 of the computer chip with in-chip cooling 603 and the inlet of the flow controller. The heat exchanger is configured to receive the heated coolant C after it passes through the computer chip with in-chip cooling 603, dissipate at least some of the heat from the coolant to the surrounding environment, and then pass the cooled coolant to the flow controller, which returns the cooled coolant C to the computer chip with in-chip cooling 603 in a closed loop manner. In one or more embodiments, the computer chip with in-chip cooling 603 may have a heat dissipation, Q, of greater than approximately 1,000 W/cm² and a heat transfer coefficient, h, greater than approximately 10,000 W/m²K.

While this invention has been described in detail with particular references to exemplary embodiments thereof, the exemplary embodiments described herein are not intended to be exhaustive or to limit the scope of the invention to the exact forms disclosed. Persons skilled in the art and technology to which this invention pertains will appreciate that alterations and changes in the described structures and methods of assembly and operation can be practiced without meaningfully departing from the principles, spirit, and scope of this invention, as set forth in the following claims.

What is claimed is:

1. A cooling system comprising:
a cooling device comprising:
a housing defining an interior chamber;
an inlet in the housing;
an outlet in the housing; and
a plurality of cooling channels at an interface surface of the housing and between the inlet and the outlet.

2. The cooling system of claim 1, further comprising a coolant in the interior chamber of the housing.

3. The cooling system of claim 1, wherein the plurality of cooling channels comprises a plurality of microfluidic channels or a plurality of nanofluidic channels.

4. The cooling system of claim 1, wherein the plurality of cooling channels comprises a combination of a plurality of microfluidic channels and a plurality of nanofluidic channels.

5. The cooling system of claim 1, further comprising a nanocoating on the plurality of cooling channels.

6. The cooling system of claim 1, further comprising a plurality of nanostructures on the plurality of cooling channels.

7. The cooling system of claim 2, further comprising a heat exchanger connected to the outlet, the heat exchanger being configured to receive the coolant from the outlet.

8. The cooling system of claim 2, further comprising a flow controller connected to the inlet, the flow controller being configured to pump the coolant into the housing through the inlet.

9. The cooling system of claim 2, wherein the coolant comprises a liquid.

10. The cooling system of claim 9, wherein the liquid is selected from the group consisting of water, a dielectric fluid, a synthetic oil, and a perfluorocarbon compound.

11. The cooling system of claim 10, wherein the liquid further comprises at least one additive.

12. The cooling system of claim 11, wherein the at least one additive is an antifreeze agent selected from the group consisting of glycerol, ethylene glycol, methylene glycol, and methanol.

13. The cooling system of claim 11, wherein the at least one additive comprises a viscosity modifier, a corrosion inhibitor, a biocidal agent, an antifoaming agent, a pH buffer, and/or a dye.

14. The cooling system of claim 2, further comprising metallic nanoparticles in the coolant.

15. The cooling system of claim 14, wherein the metallic nanoparticles comprise a metal selected from the group consisting of aluminum, copper, and silver, and a passivation layer on top of the metal.

16. The cooling system of claim 1, further comprising a plurality of pressure sensors configured to measure a pressure drop in the plurality of cooling channels, the plurality of pressure sensors comprising a first pressure sensor at the inlet and a second pressure sensor at the outlet.

17. The cooling system of claim 1, further comprising a plurality of flow sensors configured to measure a flow rate through the plurality of cooling channels, the plurality of flow sensors comprising a first flow sensor at the inlet and a second flow sensor at the outlet.

18. The cooling system of claim 1, further comprising a plurality of temperature sensors configured to measure a temperature in the plurality of cooling channels, the plurality of temperature sensors comprising a first temperature sensor at the inlet and a second temperature sensor at the outlet.

19. A computer chip with an in-chip cooling device comprising:
a housing defining an interior chamber;
a computing device in the housing;
an inlet in the housing;
an outlet in the housing; and
a plurality of cooling channels between the inlet and the outlet, wherein the plurality of cooling channels comprises a plurality of microfluidic channels, a plurality of nanofluidic channels, or a combination of the plurality of microfluidic channels and the plurality of nanofluidic channels.

20. The computer chip of claim 19, further comprising a nanocoating and/or a plurality of nanostructures on the plurality of cooling channels.

21. A computing system comprising:
a system board;
at least one of a substrate or an interposer on the system board;
a computing device on the at least one of the substrate or the interposer; and
a cooling device between the computing device and the at least one of the substrate or the interposer, wherein the cooling device comprises:
a housing defining an interior chamber and comprising an interface surface in contact with the computing device;
an inlet in the housing;
an outlet in the housing; and
a plurality of cooling channels in the interior chamber at the interface surface and between the inlet and the outlet;
a coolant in the interior chamber of the housing;
a flow controller connected to the inlet, the flow controller being configured to pump the coolant into the housing through the inlet; and
a heat exchanger connected to the outlet, the heat exchanger being configured to receive the coolant from the outlet.
